(19) United States
(12) Patent Application Publication
(10) Pub. No.: US 2006/0228562 A1
(43) Pub. Date: Oct. 12, 2006

(54) Semiconductor device, resin composition for buffer coating, resin composition for die bonding, and resin composition for encapsulating

(76) Inventors: Ken Ukawa, Tochigi (JP); Keiichiro Saito, Tochigi (JP); Hiroyuki Yasuda, Tochigi (JP); Junya Kusunoki, Tochigi (JP)

Correspondence Address: SMITH, GAMBRELL & RUSSELL, SUITE 3100, PROMENADE II, 1230 PEACHTREE STREET, N.E., ATLANTA, GA, 30307-3592, US

(21) Appl. No.: 11/388,791

(22) Filed: Mar. 24, 2006

(30) Foreign Application Priority Data
Mar. 25, 2005 (JP) P2005-090118

(51) Int. Cl. B32B 27/00; B32B 27/38; H01L 21/56; C08L 83/10; C08L 63/00; C08G 77/42

(52) U.S. Cl. 428/413; 428/447; 428/473.5; 525/476; 438/127

(57) ABSTRACT

This invention can provide a semiconductor device exhibiting excellent anti-solder reflow resistance and higher reliability in surface mounting using a lead-free solder. In accordance with the present invention, there is provided a semiconductor device formed by placing a semiconductor chip whose surface is coated with a cured resin composition for buffer coating on a pad in a lead frame via a cured resin composition for die bonding and encapsulating the semiconductor chip on the pad in the lead frame by a cured resin composition for encapsulating, wherein the cured resin composition for buffer coating has an elastic modulus of 0.5 GPa to 2.0 GPa both inclusive at 25° C.; the cured resin composition for die bonding has an elastic modulus of 1 MPa to 120 MPa both inclusive at 260° C.; and the cured resin composition for encapsulating has an elastic modulus of 400 MPa to 1200 MPa both inclusive at 260° C. and a thermal expansion coefficient of 20 ppm to 50 ppm both inclusive at 260° C., and the product of the elastic modulus of the cured resin composition for encapsulating and thermal expansion coefficient of the cured resin composition for encapsulating is 8000 to 45000 both inclusive.

This application is based on Japanese patent application NO. 2005-090118, the content of which is incorporated hereinto by reference.

### BACKGROUND

1. Technical Field

This invention relates to a semiconductor device (hereinafter, optionally referred to as a “package”) exhibiting excellent anti-solder reflow resistance and also relates to resin compositions for buffer coating (hereinafter, optionally referred to as a “buffer coating material”), resin compositions for die bonding a semiconductor chip (hereinafter, optionally referred to as a “die bonding material”) and resin compositions for encapsulating a semiconductor chip (hereinafter, optionally referred to as a “encapsulating material”) which are used in the process.

2. Related Art

There has been increased the use of a lead-free solder without lead in mounting a semiconductor device on a board from environmental consideration. Generally, a lead-free solder has a higher melting point than a conventional tin-lead eutectic solder and thus must be mounted at a higher temperature by about 20 to 30° C. during mounting a semiconductor device. This increased mounting temperature causes a larger thermal stress than usual between members constituting a semiconductor device and increase in a vapor pressure due to rapid evaporation of water in resin compositions for encapsulating, leading to tendency to defects such as delamination between members and package cracks. Furthermore, the organic insulating interlayer with low dielectric constant, which used in the most advanced semiconductor, was frequently destroyed by thermal stress in packaging because this layer is strength poverty and brittle. Thus, it has been increasingly needed to improve reliability in each member used has higher reliability for providing a semiconductor device having excellent resistance to anti-solder reflow resistance.

The most effective way for meeting such needs is to minimize water absorption from resin compositions for encapsulating. There have been proposed various approaches such as applying a low water-absorbing resin and dense filling of an inorganic filler (See, for example, Japanese Patent Application No. 2002-145995, pp. 2 to 6). However, minimization of water absorption in resin compositions for encapsulating alone cannot satisfactorily meet the requirement for higher reliability.

Another effective approach may be reducing a thermal stress in each interface between members constituting a semiconductor device. Specifically, it may be achieved by equalizing thermal extension coefficients of members, or by reducing an elastic modulus of each member for reducing a stress generated by discrepancy in a thermal expansion coefficient between members. However, partial reduction of a thermal stress alone is inadequate in a semiconductor device consisting of a plurality of components, and sometimes local reduction of a thermal stress may get worse defects in other interfaces. There has been, therefore, needed to adjust physical properties among a plurality of members for reducing a thermal stress in each interface between members.

An objective of this invention is to provide a semiconductor device exhibiting excellent anti-solder reflow resistance and reliability in surface mounting using a lead-free solder, and resin composition for buffer coating, resin composition for die bonding and resin composition for encapsulating semiconductor.

### SUMMARY OF THE INVENTION

According to an aspect of the present invention, there is provided a semiconductor device formed by placing a semiconductor chip whose surface is coated with a cured resin composition for buffer coating on a pad in a lead frame via a cured resin composition for die bonding and encapsulating the semiconductor chip on the pad in the lead frame by a cured resin composition for encapsulating, wherein

the cured resin composition for buffer coating has an elastic modulus of 0.5 GPa to 2.0 GPa both inclusive at 25° C.;

the cured resin composition for die bonding has an elastic modulus of 1 MPa to 120 MPa both inclusive at 260° C.; and

the cured resin composition for encapsulating has an elastic modulus of 400 MPa to 1200 MPa both inclusive at 260° C. and a thermal expansion coefficient of 20 ppm to 50 ppm both inclusive at 260° C., and the product of the elastic modulus of the cured resin composition for encapsulating and thermal expansion coefficient of the cured resin composition for encapsulating is 8000 to 45000 both inclusive.

According to another aspect of the present invention, there is provided a resin composition for buffer coating used for a semiconductor device formed by placing a semiconductor chip whose surface is coated with a cured resin composition for buffer coating on a pad in a lead flame via a cured resin composition for die bonding and encapsulating the semiconductor chip on the pad in the lead frame by a cured resin composition for encapsulating, wherein

the cured resin composition for buffer coating has an elastic modulus of 0.5 GPa to 2.0 GPa both inclusive at 25° C.

According to a further aspect of the present invention, there is provided a resin composition for die bonding used for a semiconductor device formed by placing a semiconductor chip whose surface is coated with a cured resin composition for buffer coating on a pad in a lead flame via a cured resin composition for die bonding and encapsulating the semiconductor chip on the pad in the lead frame by a cured resin composition for encapsulating, wherein

the cured resin composition for die bonding has an elastic modulus of 1 MPa to 120 MPa both inclusive at 260° C.

According to a further aspect of the present invention, there is provided a resin composition for encapsulating used for a semiconductor device formed by placing a semiconductor chip whose surface is coated with a cured resin composition for buffer coating on a pad in a lead frame via a cured resin composition for die bonding and encapsulating the semiconductor chip on the pad in the lead frame by a cured resin composition for encapsulating, wherein

the cured resin composition for encapsulating has an elastic modulus of 400 MPa to 1200 MPa both inclusive at 260° C. and a thermal expansion coefficient of 20 ppm to 50 ppm both inclusive at 260° C., and the product of the elastic modulus of the cured resin composition for encapsulating and thermal expansion coefficient of the cured resin composition for encapsulating is 8000 to 45000 both inclusive.

The resin composition for buffer coating, the resin composition for die bonding and the resin composition for encapsulating having the compositions as described above can provide cured materials physical properties such as an elastic modulus within the above ranges.

This invention can provide a semiconductor device exhibiting excellent anti-solder reflow resistance and reliability in mounting using a lead-free solder, and also provide resin compositions for buffer coating, resin compositions for die bonding and resin compositions for encapsulating which can be used in the process.

### BRIEF DESCRIPTION OF THE DRAWINGS

The above and other objects, advantages and features of the present invention will be more apparent from the following description taken in conjunction with the accompanying drawings, in which:

FIG. 1 is a schematic cross-sectional view of a semiconductor device according to the present invention.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purpose.

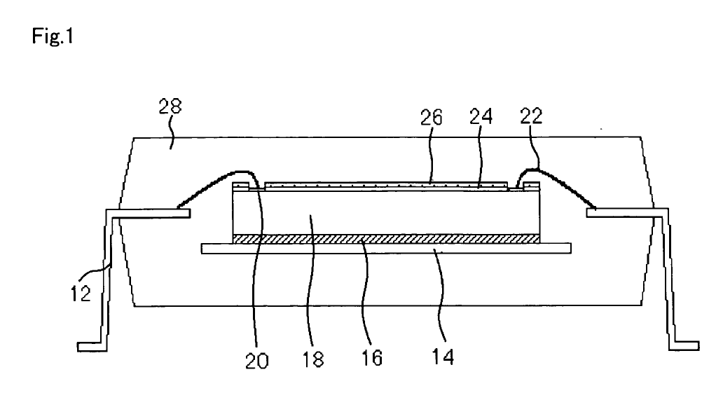

A semiconductor device of this invention is formed by placing a semiconductor chip whose surface is coated with a cured resin composition for buffer coating (a buffer coating film) on a pad in a lead frame via a cured resin composition for die bonding (a cured die bonding material) and encapsulating the semiconductor chip on the pad in the lead frame by a cured resin composition for encapsulating (a cured encapsulating material). There will be described the semiconductor device of this invention with reference to the drawings, but a semiconductor device of this invention is not limited to the configuration shown in FIG. 1.

As shown in a schematic cross-sectional view of FIG. 1, a semiconductor device 10 has, for example, a semiconductor chip 18 placed on a pad 14 in the lead frame 12 via a cured die bonding material 16. In semiconductor chip 18, there are formed multilayer integrated circuits. In addition, on the element-forming surface of the semiconductor chip 18, there is formed a passivation film 24 and a buffer coating film 26. An opening is formed on surface of the semiconductor chip 18. An opening is used in connecting to a bonding wire 22, and the bonding pad 20 is exposed in bottom of the opening. The semiconductor chip 18 placed on a pad 14 in the lead frame 12 via a cured die bonding material 16. Then, a bonding wire 22 strain between the lead frame 12 and the semiconductor chip 18 so that these are connected electrically. Finally, the semiconductor device 10 is formed by encapsulating with a cured encapsulating material 28.

In the semiconductor device 10 having such a configuration, the cured die bonding material 16 is in contact with, for example, the pad 13 and the rear surface of the semiconductor chip 18. The buffer coating film 26 is in contact with, for example, the cured encapsulating material 28 and the passivation film 24. The cured encapsulating material 28 is in contact with, for example, the buffer coating film 26, the passivation film 24, the semiconductor chip 18 and the lead frame 12. In this invention, the cured die bonding material 16, the buffer coating film 26 and the cured encapsulating material 28 have physical properties such as an elastic modulus within given ranges, so that a stress generated due to discrepancy in a thermal expansion coefficient between members can be reduced, to provide a semiconductor device highly reliable even in mounting using a lead-flee solder.

There will be detailed resin compositions for the buffer coating film 26, the cured die bonding material 16 and the cured encapsulating material 28 as described above.

Resin Composition for Buffer Coating

There are no particular restrictions to a resin composition for buffer coating used in the present invention as long as a cured material formed from the resin composition has an elastic modulus of 0.5 GPa to 2.0 GPa both inclusive at 25° C. An elastic modulus of the cured material can be determined by measuring a tensile strength in accordance with JIS K-6760, and calculating a Young's elastic modulus at 25° C. from the resulting SS curve.

A resin composition for buffer coating contains, for example, an epoxy-containing cyclic olefin resin, a photoacid generator and further, as necessary, a solvent, a sensitizer, an acid quencher, a leveling agent, an antioxidant, a flame retardant, a plasticizer and a silane coupling agent.

An epoxy-containing cyclic olefin resin used in the resin composition for buffer coating may be an addition (co)polymer containing a structural unit derived from a norbornene type monomer represented by general formula (1):

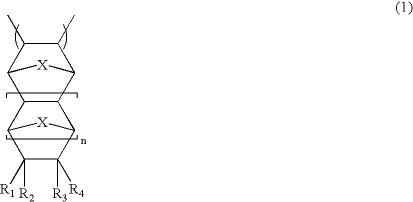

(wherein Xs independently represent O, CH₂ or (CH₂)₂, a plurality of Xs may be, if present, the same or different; n is an integer of 0 to 5; and R1 to R4 independently represent hydrogen, an alkyl-, alkenyl-, alkynyl-, allyl-, aryl-, aralkyl- or ester-containing organic group, an ketone-containing organic group, an ether-containing organic group or an epoxy-containing organic group and R1 to R4 may be the same or different in a plurality of structural units, provided that at least one of R1 to R4 in the total structural units is an epoxy-containing organic group).

A preferable epoxy-containing organic group is a glycidyl ether group.

A content of the structural unit represented by general formula (1) in the (co)polymer can be determined such that exposure can initiate crosslinking to give a crosslinking density resistant to a developing solution. Generally, a content of the structural unit represented by general formula (1) in a polymer is 5 mol % to 95 mol % both inclusive, preferably 20 mol % to 80 mol % both inclusive, more preferably 30 mol % to 70 mol % both inclusive.

A photoacid generator used in the resin composition for buffer coating may be any known photoacid generator. A photoacid generator initiates crosslinking via an epoxy group and improves adhesiveness to a substrate by subsequent curing.

Examples of a preferred photoacid generator include onium salts, halogen compounds, sulfates and mixtures of these. For example, a cationic part in an onium salt may be selected from diazonium, ammonium, iodonium, sulfonium, phosphonium, arsonium and oxonium cations. A counter anion to the cation may be any compound which can form a salt with the onium cation with no limitations. Examples of a counter anion include, but not limited to, boric acid, arsonic acid, phosphoric acid, antimonic acid, sulfates, carboxylic acids and their chlorides.

Examples of an onium salt as a photoacid generator include triphenylsulfonium tetrafluoroborate, triphenylsulfonium hexafluoroborate, triphenylsulfonium tetrafluoroarsenate, triphenylsulfonium tetrafluorophosphate, triphenylsulfonium tetrafluorosulfate, 4-thiophenoxydiphenylsulfonium tetrafluoroborate, 4-thiophenoxydiphenylsulfonium tetrafluoroantimonate, 4-thiophenoxydiphenylsulfonium tetrafluoroarsenate, 4-thiophenoxydiphenylsulfonium tetrafluorophosphate, 4-thiophenoxydiphenylsulfonium tetrafluorosulfonate, 4-t-butylphenyldiphenylsulfonium tetrafluoroborate, 4-t-butylphenyldiphenylsulfonium tetrafluorosulfonium, 4-t-butylphenyldiphenylsulfonium tetrafluoroantimonate, 4-t-butylphenyldiphenylsulfonium trifluorophosphonate, 4-t-butylphenyldiphenylsulfonium trifluorosulfonate, tris(4-methylphenyl)sulfonium trifluoroborate, tris(4-methylphenyl)sulfonium tetrafluoroborate, tris(4-methylphenyl)sulfonium hexafluoroarsenate, tris(4-methylphenyl)sulfonium hexafluorophosphate, tris(4-methylphenyl)sulfonium hexafluorosulfonate, tris(4-methoxyphenyl)sulfonium tetrafluoroborate, tris(4-methylphenyl)sulfonium hexafluoroantimonate, tris(4-methylphenyl)sulfonium hexafluorophosphate, tris(4-methylphenyl)sulfonium trifluorosulfonate, triphenyliodonium tetrafluoroborate, triphenyliodonium hexafluoroantimonate, triphenyliodonium hexafluoroarsenate, triphenyliodonium hexafluorophosphate, triphenyliodonium trifluorosulfonate, 3,3-dinitrodiphenyliodonium tetrafluoroborate, 3,3-dinitrodiphenyliodonium hexafluoroantimonate, 3,3-dinitrodiphenyliodonium hexafluoroarsenate, 3,3-dinitrodiphenyliodonium trifluorosulfonate, 4,4-dinitrodiphenyliodonium tetrafluoroborate, 4,4-dinitrodiphenyliodonium hexafluoroantimonate, 4,4-dinitrodiphenyliodonium hexafluoroarsenate and 4,4-dinitrodiphenyliodonium trifluorosulfonate, which can be used alone or in combination.

Examples of a halogen compound as a photoacid generator include 2,4,6-tris(trichloromethyl)triazine, 2-allyl-4,6-bis(trichloromethyl)triazine, α,β,α-tribromomethylphenylsulfone, α,α-2,3,5,6-hexachloroxylene, 2,2-bis(3,5-dibromo-4-hydroxyphenyl)-1,1,1,3,3,3-hexafluoroxylene, 1,1,1-tris(3,5-dibromo-4-hydroxyphenyl)ethane and mixtures of these.

Examples of a sulfate as a photoacid generator include, but not limited to, 2-nitrobenzyltosylate, 2,6-dinitrobenzyltosylate, 2,4-dinitrobenzyltosylate, 2-nitrobenzylmethylsulfonate, 2-nitrobenzylacetate, 9,10-dimethoxyanthracene-2-sulfonate, 1,2,3-tris(methanesulfonyloxy)benzene, 1,2,3-tris(ethanesulfonyloxy)benzene, 1,2,3-tris(propanesulfonyloxy)benzene.

Preferably, a photoacid generator is selected from 4,4′-di-t-butylphenyliodonium triflate, 4,4′,4″-tris(t-butylphenyl)sulfonium triflate, diphenyliodonium tetrakis(pentafluorophenyl)borate, triphenylsulfonium diphenyliodonium tetrakis(pentafluorophenyl)borate, 4,4′-di-t-butylphenyliodonium tetrakis(pentafluorophenyl)borate, tris(t-butylphenyl)sulfonium tetrakis(pentafluorophenyl)borate, (4-methylphenyl-4-(1-methylethyl)phenyliodonium tetrakis(pentafluorophenyl)borate and mixtures of these.

A blending rate of a photoacid generator in a resin composition for buffer coating used in this invention is 0.1 parts by weight to 100 parts by weight both inclusive, more preferably 0.1 parts by weight to 10 parts by weight both inclusive to 100 parts by weight of a cyclic olefin resin in the light of, for example, a crosslinking density of a cured material and adhesiveness to a substrate.

A resin composition for buffer coating used in this present may contain, if necessary, a sensitizer for improving photosensitivity.

A sensitizer can be added to an extent that it can extend the range in which a photoacid generator can be activated while a crosslinking reaction of a polymer is not directly affected. An optimal sensitizer is a compound having a maximum absorbency index near a light source used and capable of efficiently transferring absorbed energy to a photoacid generator.

Examples of a sensitizer for a photoacid generator include cyclic aromatics such as anthracenes, pyrenes and parylene. Examples of a compound having an anthracene moiety include 2-isopropyl-9H-thioxanthen-9-ene, 4-isopropyl-9H-thioxanthene-9-one, 1-chloro-4-propoxythioxanthene, phenothiazine and mixtures of these. A blending rate of a photoacid generator in a resin composition for buffer coating used in this invention is 0.1 parts by weight to 10 parts by weight both inclusive, more preferably 0.2 parts by weight to 5 parts by weight both inclusive to 100 parts by weight of a cyclic olefin resin in the light of its ability to extend the wavelength range in which a photoacid generator can be activated and absence of direct effects on a crosslinking reaction of a polymer. When a light source is a long-wavelength ray such as g-ray (436 nm) and i-ray (365 nm), a sensitizer is effective for activating a photoacid generator.

A small amount of an acid scavenger may be, if necessary, added to a resin composition for buffer coating used in this invention, to improve resolution. An acid scavenger absorbs an acid diffusing into an unexposed area during a photochemical reaction. Examples of an acid scavenger include, but not limited to, secondary and tertiary amines such as pyridine, lutidine, phenothiazine, tri-n-propylamine and triethylamine. A blending rate of an acid scavenger is 0.01 parts by weight to 0.5 parts by weight both inclusive to 100 parts by weight of a cyclic olefin resin in the light of absorption of an acid diffusing into an unexposed area and improvement of resolution.

A buffer coating resin composition used in this invention may further contain, if necessary, additives such as a leveling agent, an antioxidant, a flame retardant, a plasticizer and a silane coupling agent.

A resin composition for buffer coating used in this invention is prepared as a varnish by dissolving these components in a solvent The solvent may be a nonreactive or reactive solvent. A nonreactive solvent acts as a carrier for a polymer or an additive and removed in the process of application or curing. A reactive solvent has a reactive group compatible with a curing agent added to a resin composition.

A nonreactive solvent may be a hydrocarbon or aromatic compound. Examples of a hydrocarbon solvent include, but not limited to, alkanes and cycloalkanes such as pentane, hexane, heptane, cyclohexane and decahydronaphthalene. Examples of an aromatic solvent include benzene, toluene, xylene and mesitylene. Other useful solvents include diethyl ether, tetrahydrofuran, anisol, acetates, esters, lactones, ketones and amides.

Examples of a reactive solvent include cycloethers such as cyclohexene oxide and α-pinene oxide; aromatic cycloethers such as [methylene-bis(4,1-phenylenoxymethylene)]bisoxirane;cycloaliphatic vinyl ethers such as 1,4-cyclohexanedimethanol divinyl ether, and aromatic compounds such as bis(4-vinylphenyl)methane, which can be used alone or in combination. Preferred are mesitylene and decahydronaphthalene. These are optima for applying a resin on a substrate made of, for example, silicon, silicon oxide, silicon nitride and silicon oxynitride.

A resin composition for buffer coating used in this invention preferably contain an epoxy-containing cyclic olefin resin, a photoacid generator, a sensitizer and an acid scavenger.

Specifically, when the amount of the epoxy-containing cyclic olefin resin is 100 parts by weight,

a content of the photoacid generator is 0.1 parts by weight to 100 parts by weight both inclusive, preferably 0.1 parts by weight to 10 parts by weight both inclusive,

a content of the sensitizer is 0.1 parts by weight to 10 parts by weight both inclusive, preferably 0.2 parts by weight to 5 parts by weight both inclusive, and

a content of the acid scavenger is 0.01 parts by weight to 0.5 parts by weight both inclusive. These ranges may be combined as appropriate.

A resin composition for buffer coating having a composition as described above can provide a cured material having an elastic modulus of 0.5 GPa to 2.0 GPa both inclusive at 25° C.

A resin solid content of a resin composition for buffer coating used in this invention is 5 wt % to 60 wt % both inclusive, more preferably, 30 wt % to 55 wt % both inclusive, further preferably 35 wt % to 45 wt %. A solution viscosity is 10 cP to 25,000 cP both inclusive, preferably 100 cP to 3,000 cP both inclusive.

A resin composition for buffer coating used in this invention can be prepared by, but not limited to, simply blending an epoxy-containing cyclic olefin resin and photoacid generator, and, when necessary, a solvent, a sensitizer, an acid scavenger, a leveling agent, an antioxidant, a flame retardant, a plasticizer, a silane coupling agent and so on.

For controlling an elastic modulus of a cured resin composition for buffer coating used in this invention to 0.5 GPa to 2.0 GPa both inclusive at 25° C., it is desirable to use a polynorbornene.

Resin Composition for Die Bonding

A resin composition for die bonding used in this invention gives a cured material having an elastic modulus of 1 MPa to 120 MPa both inclusive at 260° C. The resin composition for die bonding may be provided in the form of, but not limited to, a resin paste and a resin film.

<Resin Paste>

A resin paste which can be used as a resin composition for die bonding in this invention is characterized in that it contains a thermosetting resin and a filler as main components and gives a cured material having an elastic modulus of 1 MPa to 120 MPa both inclusive at 260° C. An elastic modulus of a cured material can be determined by measuring an elastic modulus using a dynamic viscoelasticity measuring apparatus under the conditions of a temperature range: −100° C. to 330° C., a rate of rising temperature: 5° C./min and a frequency: 10 Hz and calculating a storage elastic modulus at 260° C.

A resin paste contains a thermosetting resin, curing agent, curing accelerator and so on. It is desirably, but not limited to. a liquid at an ambient temperature because it is a material for preparing a paste.

Examples of a thermosetting resin used in the above resin paste include compounds having a radical-polymerizable functional group such as liquid cyanate resins, liquid epoxy resins, various acrylic resins, maleimide resins, aryl-containing triaryl-isocyanurates, which can be used alone or in combination of two or more. Examples of a liquid epoxy resin include bisphenol-A type epoxy resins, bisphenol-F type epoxy resins, bisphenol-E type epoxy resins, alicyclic epoxy resins, aliphatic epoxy resins and glycidylamine type liquid epoxy resins.

In this invention, a thermosetting resin which is a solid at an ambient temperature may be also added as a thermosetting resin used in a resin paste to an extent that it does not adversely affect properties. Examples of a thermosetting resin which is a solid at an ambient temperature and can be combined, include, but not limited to, epoxy resins such as biphenol-A, bisphenol-F, phenol novolac, polyglycidyl ethers prepared by a reaction of a cresol novolac with epichlorohydrin, biphenyl type epoxy resins, stilbene type epoxy resins, hydroquinone type epoxy resins, triphenolmethane type epoxy resins, phenolaralkyl type (having a phenylene or diphenylene moiety) epoxy resins, epoxy resins having a naphthalene moiety and dicyclopentadiene type epoxy resins. Monoepoxy resins may be also used, including n-butylglycidyl ether, versatic acid glycidyl ester, styrene oxide, ethylhexyl glycidyl ether, phenylglycidyl ether, cresyl glycidyl ether and butylphenylglycidyl ether. Examples of a maleimide resin include bismaleimide resins such as
N,N′-(4,4′-diphenylmethane)bismaleimide,
bis(3-ethyl-5-methyl4-maleimidephenyl)methane,
2,2-bis[4-(4-maleimidephenoxy)phenyl]propane.

Examples of a curing catalyst when using a cyanate resin as a thermosetting resin in a resin paste include metal complexes such as copper-acetylacetonate and zinc-acetylacetonate. Examples of a curing agent when using an epoxy resin as a thermosetting resin include phenol resins, aliphatic amines, aromatic amines, dicyandiamides, dicarboxylic acid dihydrazides and carboxylic anhydrides. An initiator when using a compound having a radical-polymerizable functional group as a thermosetting resin may be any catalyst commonly used in radical polymerization; for example, a thermal radical polymerization initiator such as organic peroxides.

When using an epoxy resin as a thermosetting resin in a resin paste, examples of an agent as both curing accelerator and curing agent may be selected from common imidazoles including various imidazoles including common imidazoles such as 2-methylimidazole, 2-ethylimidazole, 2-phenyl-4-methyl-5-hydroxymethylimidazole and 2-C₁₁H₂₃-imidazole; 2,4-diamino-6-{2-methylimidazole-(1)}-ethyl-S-triazine prepared by addition of triazine or an isocyanuric acid; and their isocyanate adducts, which can be used alone or in combination of two or more.

A filler which can be used in a resin paste may be an inorganic or organic filler. Examples of an inorganic filler include metal powders such as gold powder, silver powder, copper powder and aluminum powder, fused silica, crystal silica, alumina, aluminum nitride and talc. Examples of an organic filler include silicone resins, fluororesins such as polytetrafluoroethylene, acrylic resins such as polymethyl methacrylate and crosslinking products of benzoguanamine or melamin with formaldehyde. Among these, metal powders are used for endowing a paste with electroconductivity and/or thermal conductivity. Particularly preferred is silver powder because many types can be obtained in terms of a particle size and a shape and it is readily available.

In a filler used in a resin paste, the amount of ionic impurities such as halogen ions and alkali metal ions is preferably 10 ppm or less. Its shape may be flakes, scales, dendrites and spheres. A particle size used depends on a viscosity of a resin paste needed, but a preferred filler generally has an average particle size of 0.3 μm to 20 μm both inclusive and a maximum particle size of about 50 μm or less. When an average particle size is within the above range, increase in a viscosity or bleeding due to resin overflow during application or curing can be prevented. A filler with the maximum particle size within the above range can prevent a needle hole from being clogged during paste application. As a result, the needle can be continuously used. Alternatively, a relatively coarse filler and a relatively fine filler can be used in combination, and various fillers in terms of a type and a shape can be mixed as appropriate.

For endowing a resin paste with requisite properties, an appropriate filler can be added, including a nanoscale filler having a particle size of about 1 nm to 100 nm both inclusive, a composite of silica and an acrylic compound and a complex filler of an organic and an inorganic materials such as an organic filler whose surface is coated with a metal.

A filler used in a resin paste may be preliminarily surface-treated with, for example, a silane coupling agent such as alkoxysilanes, allyloxysilanes, silazanes and organoaminosilanes.

A resin paste for die bonding which can be used in this invention may contain, when necessary, additives such as silane coupling agents, titanate coupling agents, low stress additive, pigments, dyes, defoaming agents, surfactants and solvent as long as properties needed for an application are not deteriorated.

A resin paste for die bonding used in this invention preferably contains an epoxy resin, a curing agent and an inorganic filler.

Specifically an epoxy resin is contained in the amount of 1 equivalent to 10 equivalent both inclusive, preferably 1 equivalent to 6 equivalent both inclusive to one equivalent of a curing agent. The amount of an inorganic filler is 70 wt % to 90 wt % both inclusive, preferably 70 wt % to 85 wt % both inclusive in the resin paste. These ranges may be combined as appropriate.

A resin paste for die bonding having the above composition can be used to give a cured material having an elastic modulus of 1 MPa to 120 MPa both inclusive at 260° C.

A resin paste for die bonding which can be used in this invention may be prepared by, but not limited to, premixing individual components and kneading the premix using appropriate means such as three rollers and a wet bead mill to give a resin paste which is then defoamed in vacuo.

For giving a cured material of a resin paste for die bonding which can be used in this invention which has an elastic modulus of 1 MPa to 120 MPa both inclusive at 260° C., it is further preferable that a thermosetting resin is a liquid epoxy resin such as hydrogenated bisphenol-A type epoxy resins, 1,4-cyclohexanedimethanol diglycidyl ether, 1,4-butanediol diglycidyl ether and 1,6-hexanediol diglycidyl ether,

a solid epoxy resin such as dicyclopentadiene type epoxy resins;

compounds such as polybutadienes, polyisoprenes, polyalkylene oxides, aliphatic polyesters and polynorbornenes which having an intramolecular radical-polymerizable functional group (acryloyl, methacryloyl, acrylamide, maleimide, vinyl ester, vinyl ether and so on).

Thus, many non-aromatic moieties such as an aliphatic chain (hydrocarbon chain) and an alicyclic moiety can be introduced into a resin structure to give a cured material having an elastic modulus within the above range. Furthermore, it is also effective to use a low stress additive such as a carboxyl-terminal butadiene-acrylonitrile copolymer and a phthalic acid ester.

<Resin Film>

A resin film which can be used as a resin composition for die bonding in this invention is characterized in that it contains a thermoplastic resin and a thermosetting resin as main components and its cured material has an elastic modulus of 1 MPa to 120 MPa both inclusive at 260° C. An elastic modulus of a cured material can be determined as described above for a resin paste.

Examples of a thermoplastic resin used in the resin film for die bonding include polyimide resins such as polyimide resins and polyether imide resins; polyamide resins such as polyamide resin, polyamideimide resin; and acrylic resins. Among these, polyimide resins are preferable. Thus, both initial adhesiveness and heat resistance can be achieved. As used herein, the term “initial adhesiveness” refers to adhesiveness in the initial stage when a semiconductor chip is attached to a supporting member via a resin film for die bonding, that is, adhesiveness before curing the resin film for die bonding.

The polyimide resin can be prepared by a polycondensation reaction of, a tetracarboxylic dianhydride, a diaminopolysiloxane represented by general formula (2) and an aromatic or aliphatic diamine.

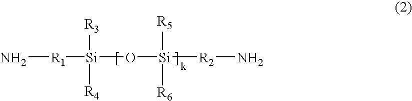

In general formula (2), R1 and R2 independently represent an aliphatic hydrocarbon group having 1 to 4 carbon atoms or aromatic hydrocarbon; and R3, R4, R5 and R6 independently represent an aliphatic hydrocarbon group having 1 to 4 carbon atoms or aromatic hydrocarbon.

Examples of a tetracarboxylic dianhydride used as a starting material for the above polyimide resin include 3,3′,4,4′-biphenyltetracarboxylic dianhydride, 3,3′,4,4′-benzophenone tetracarboxylic dianhydride, pyromellitic dianhydride, 4,4′-oxydiphthalic dianhydride and ethyleneglycol bis trimellitic dianhydride. Among others, 4,4′-oxydiphthalic dianhydride is preferable in terms of adhesiveness. These tetracarboxylic dianhydrides may be used alone or in combination of two or more.

Examples of a diaminopolysiloxane represented by formula (2) as a starting material for the above polyimide resin include ω,ω′-bis(2-aminoethyl)polydimethylsiloxane, ω,ω′-bis(4-aminophenyl)polydimethylsiloxane and α,ω-bis(3-aminopropyl)polydimethylsiloxane. Particularly preferred are those having a k value in formula (2) of 1 to 25, preferably 1 to 10 in terms of adhesiveness. Furthermore, for improving adhesiveness, these can be used, if necessary, in combination of two or more.

Examples of a diamine used as a starting material for the above polyimide resin include 3,3′-dimethyl-4,4′-diaminobiphenyl, 4,6-dimethyl-m-phenylenediamine, 2,5-dimethyl-p-phenylenediamine, 2,4-diaminomesitylene, 4,4′-methylenedi-o-toluidine, 4,4′-methylenediamine-2,6-xylidine, 4,4′-methylene-2,6-diethylaniline, 2,4-toluenediamine, m-phenylenediamine, p-phenylenediamine, 4,4′-diaminodiphenylpropane, 3,3′-diaminodiphenylpropane, 4,4′-diaminodiphenylethane, 3,3′-diaminodiphenylethane, 4,4′-diaminodiphenylmethade, 3,3′-diaminodiphenylmethane, 4,4′-diaminodiphenyl sulfide, 3,3′-diaminodiphenyl sulfide, 4,4′-diaminodiphenyl sulfone, 3,3′-diaminodiphenyl sulfone, 4,4′-diaminodiphenyl ether, 3,3′-diaminodiphenyl ether, benzidine, 3,3′-diaminobiphenyl, 3,3′-dimethyl-4,4′-diaminobiphenyl, 3,3′-dimethoxybenzidine, bis(p-amiocyclohexyl)methane, bis(p-β-amino-t-butylphenyl)ether, bis(p-β-methyl-δ-aminopentyl)benzene, p-bis(2-methyl-4-aminopentyl)benzene, 1,5-diaminonaphthalene, 2,6-diaminonaphthalene, 2,4-bis(β-amino-t-butyl)toluene, 2,4-diaminotoluene, m-xylene-2,5-diamine, p-xylene-2,5-diamine, m-xylylenediamine, p-xylylenediamine, 2,6-diaminopyridine, 2,5-diaminopyridine, 2,5-diamino-1,3,4-oxadiazole, 1,4-diaminocyclohexane, piperazine, methylenediamine, ethylenediamine, tetramethylenediamine, pentamethylenediamine, hexamethylenediamine, 2,5-dimethylhexamethylenediamine, 3-methoxyhexamethylenediamine, heptamethylenediamine, 2,5-dimethylheptamethylenediamine, 3-methylheptamethylenediamine, 4,4-dimethylheptamethylenediamine, octamethylenediamine, nonamethylenediamine, 5-methylnonamethylenediamine, decamethylenediamine, 1,3-bis(3-aminophenoxy)benzene, 2,2-bis[4-(4-aminophenoxy)phenyl]propane, 1,3-bis(4-aminophenoxy)benzene, bis-4-(4-aminophenoxy)phenyl sulfone and bis-4-(3-aminophenoxy)phenyl sulfone. Among others, preferred are 2,2-bis[4-(4-aminophenoxy)phenyl]propane and 1,3-bis(3-aminophenoxy)benzene in terms of adhesiveness. These diamines may be used alone or in combination of two or more.

In the polycondensation reaction to provide the polyimide resin, a equivalent ratio of acid component/amine component is an important factor in determining a molecular weight of a polyimide resin obtained Furthermore, it has been well-known that there are correlation between a molecular weight and physical properties of a polymer obtained, particularly between a number average molecular weight and mechanical properties. The larger a number average molecular weight is, the better mechanical properties are. It is, therefore, necessary that a certain higher molecular weight is necessary for realizing practically satisfactory strength

In this invention, it is preferable that an equivalent ratio “r” of acid component/amine component in the polyimide resin is within the range of
0.900≦r≦1.06
particularly,
0.975≦r≦1.025
in terms of both mechanical strength and heat resistance, wherein r=[the total equivalent number of acid components]/[the total equivalent number of amine components].

When r is within the above range, good adhesiveness can be achieved without problems such as gas generation and foaming. Furthermore, a dicarboxylic anhydride or monoamine can be added for controlling a molecular weight of the polyimide resin as long as the above acid/amine molar ratio “r” is within the above range.

The reaction of the tetracarboxylic dianhydride with the diamine is effected in an aprotic polar solvent by a known process. Examples of an aprotic polar solvent include N,N-dimethylformamide (DMF), N,N-dimethylacetamide (DMAC), N-methyl-2-pyrrolidone (NMP), tetrahydrofuran (THF), diglyme, cyclohexanone and 1,4-dioxane (1,4-DO), which can be used alone or in combination of two or more.

Here, a non-polar solvent which is compatible with the above aprotic polar solvent may be added. Commonly used examples of such a solvent include aromatic hydrocarbons such as toluene, xylene and solvent naphtha. A content of the non-polar solvent in the mixed solvent is preferably 30 wt % or less because the solvent may have insufficient dissolving power, leading to precipitation of a polyamic acid when a non-polar solvent is contained in more than 30 wt %.

The reaction for the aromatic tetracarboxylic dianhydride with the diamine is desirably conducted by dissolving a well-dried diamine component in a dried and purified reaction solvent described above and then adding a well-dried tetracarboxylic dianhydride with a ring closure rate of 98% or more, more preferably 99% or more to the solution.

The polyamic acid solution prepared as described above is heated in an organic solvent for initiating dehydration, that is, imidation by ring closure, to give a polyimide resin. Water generated by the imidation reaction, which interferes with the ring-closure reaction, is removed by adding an organic solvent insoluble in water to the system and then azeotropically removing water from the system using an appropriate apparatus such as a Dean-Stark trap. A well-known organic solvent insoluble in water is dichlorobenzene, which may, however, cause contamination with chlorine-containing materials in an electronics application. It is, therefore, preferable to use one of the above aromatic hydrocarbons. A catalyst for the imidation reaction may be selected from acetic anhydride, β-picoline and pyridine.

In this invention, a higher imidation rate in the above polyimide resin is more preferable. A lower imidation rate is undesirable because heat in use may cause imidation, leading to water generation. Thus, it is desirable to achieve an imidation rate of 95% or more, more preferably 98% or more.

Examples of a curable resin used in the above resin film for die bonding include thermosetting resins, UV-curing resins and electron-beam curing resins. A curable resin may contains a resin having effect as a curing agent as described later.

The above curable resin preferably contains a thermosetting resin, to significantly improve heat resistance (particularly, anti-solder reflow resistance at 260° C.).

Examples of the above thermosetting resin include novolac type phenol resins such as phenol novolac resins, cresol novolac resins and bisphenol A novolac resins; phenol resins such as resole phenol resins; bisphenol type epoxy resins such as bisphenol A epoxy resins and bisphenol F epoxy resins; novolac type epoxy resins such as novolac epoxy resins and cresol novolac epoxy resins; epoxy resins such as biphenyl type epoxy resins, stilbene type epoxy resins, triphenolmethane type epoxy resins, alkyl-modified triphenolmethane type epoxy resins, triazine-nucleus containing epoxy resins and dicyclopentadiene-modified phenol type epoxy resins; urea resins; triazine-ring containing resins such as melamine resins; unsaturated polyester resins; bis-maleimide resins; polyurethane resins; diallyl phthalate resins; silicone resins; benzoxazine-ring containing resins; and cyanate resins, which may be used alone or in combination. Among these, particularly preferred are epoxy resins. Thus, heat resistance and adhesiveness can be further improved.

There are no particular restrictions to the above epoxy resin as long as it has at least two intramolecular epoxy groups and is compatible to a thermoplastic resin (here, a polyimide resin), but is preferably soluble in a solvent used in preparing the polyimide resin. Examples of such an epoxy resin include cresol novolac type epoxy compounds, phenol novolac type epoxy compounds, bisphenol-A type diglycidyl ethers, bisphenol-F type diglycidyl ethers, bisphenol-A epichlorohydrin type epoxy compounds, diphenyl ether type epoxy compounds, biphenyl type epoxy compounds and hydrogenated bisphenol-A type epoxy compounds.

A melting point of the epoxy resin is preferably, but not limited to, 50° C. to 150° C. both inclusive, particularly 60° C. to 140° C. both inclusive. When a melting point is within the above range, low-temperature adhesiveness can be particularly improved.

The melting point can be evaluated from a summit temperature in an endothermic peak in crystal melting when a temperature is raised at a rate of 5° C./min from room temperature using, for example, a differential scanning calorimeter.

A content of the above thermosetting resin is preferably, but not limited to, 1 part by weight to 100 parts by weight both inclusive, particularly 5 parts by weight to 50 parts by weight both inclusive to 100 parts by weight of the thermoplastic resin. When the content is within the above range, heat resistance and toughness of a resin film can be improved.

When the above curable resin is an epoxy resin, the resin film preferably contains a curing agent (particularly, a phenol curing agent).

Examples of the curing agent include amine curing agents including aliphatic polyamines such as diethylenetriamine (DETA), triethylenetetramine (TETA) and meta-xylylenediamine (MXDA); aromatic polyamines such as diaminodiphenylmethane (DDM), m-phenylenediamine (MPDA) and diaminodiphenyl sulfone (DDS) and polyamides such as dicyandiamide (DICY) and organic acid dihydrazides; acid anhydride curing agents including alicyclic acid anhydrides (liquid acid anhydrides) such as hexahydrophathalic anhydride (HHPA) and methyltetrahydrophthalic anhydride (MTHPA) and aromatic acid anhydrides such as trimellitic anhydride (TMA), piromellitic anhydride (PMDA) and benzophenone tetracarboxylic acid (BTDA); and phenol curing agents such as phenol resins. Among these, preferred are phenol curing agents; specifically, bisphenols such as bis(4-hydroxy-3,5-dimethylphenyl)methane (generally called tetramethylbisphenol F), 4,4′-sulfonyl diphenol, 4,4′-isopropylidene diphenol (generally, called bisphenol A), bis(4-hydroxyphenyl)methane, bis(2-hydroxyphenyl)methane, (2-hydroxyphenyl)(4-hydroxyphenyl)methane and a three-component mixture of bis(4-hydroxyphenyl)methane, bis(2-hydroxyphenyl)methane and (2-hydroxyphenyl)(4-hydroxyphenyl)methane (for example, bisphenol F-D, Honshu Chemical Industry Co., Ltd.); dihydroxybenzenes such as 1,2-benzene diol, 1,3-benzene diol and 1,4benzene diol; trihydroxybenzenes such as 1,2,4-benzene triol; various isomers of dihydroxynaphthalenes such as 1,6-dihydroxynaphthalene; and various isomers of biphenols such as 2,2′-biphenol and 4,4′-biphenol.

A content of the curing agent in the epoxy resin (particularly, a phenol curing agent) is preferably, but not particularly limited to, 0.5 equivalent to 1.5 equivalent both inclusive, particularly 0.7 equivalent to 1.3 equivalent both inclusive to one equivalent of the epoxy resin. When the content is within the above range, heat resistance can be improved and deterioration in a shelf life can be prevented.

It is preferable, but not essential, that the resin film for die bonding additionally contains a silane coupling agent, to further improve adhesiveness.

The above silane coupling agent is preferably selected from those which are compatible with a thermoplastic resin (here, a polyimide resin) and an epoxy compound and adequately soluble in a solvent used in preparation of the polyimide resin. Examples of such an agent include vinyl-trichlorosilane, vinyl-triethoxysilane, γ-methacryloxypropyl-trimethoxysilane, γ-glycidoxypropyl-trimethoxysilane, γ-mercaptopropyl-trimethoxysilane, N-β(aminoethyl)γ-aminopropyl-trimethoxysilane, N-β(aminoethyl)γ-aminopropylmethyl-dimethoxysilane, γ-aminopropyl-triethoxysilane and N-phenyl-γ-aminopropyltrimethoxysilane. Preferred is N-phenyl-γ-aminopropyltrimethoxysilane in the light of adhesiveness.

A content of the silane coupling agent is preferably 0.01 parts by weight to 20 parts by weight both inclusive, more preferably 1 part by weight to 10 parts by weight both inclusive to 100parts by weight of the thermoplastic resin. When the content is within the range, good adhesiveness can be achieved.

It is preferable, but not essential, that the resin film for die bonding additionally contains a filler, to further improve heat resistance.

Examples of the filler include inorganic fillers such as silver, titanium oxide, silica and mica; and fine particulate organic fillers such as silicone rubbers and polyimides. Among these, preferred are inorganic fillers, particularly silica. Thus, heat resistance can be further improved.

A content of the filler (particularly, an inorganic filler) is preferably, but not limited to, 1 part by weight to 100 parts by weight both inclusive, particularly 10 parts by weight to 50 parts by weight both inclusive to 100 parts by weight of the thermoplastic resin. When the content is within the above range, heat resistance and adhesiveness can be improved.

An average particle size of the filler (particularly, an inorganic filler) is preferably, but not limited to, 0.1 μm to 25 μm both inclusive, particularly 0.5 μm to 20 μm both inclusive. When the average particle size is within the above range, heat resistance can be improved and deterioration in adhesiveness of the resin film for die bonding can be prevented.

The resin film for die bonding preferably contains a thermoplastic resin, a curable resin and a silane coupling agent and, if necessary, a filler.

Specifically, when the thermoplastic resin is contained in 100 parts by weight,

a content of the curable resin is 1 part by weight to 100 parts by weight both inclusive, preferably 5 parts by weight to 50 parts by weight both inclusive, and

a content of the silane coupling agent is 0.01 parts by weight to 20 parts by weight both inclusive, preferably 1 part by weight to 10 parts by weight both inclusive. Furthermore, if necessary, a filler (particularly, an inorganic filler) is contained in 1 part by weight to 100 parts by weight both inclusive, preferably 10 parts by weight to 50 parts by weight both inclusive to 100 parts by weight of the thermoplastic resins These ranges can be combined as appropriate.

Using a resin film for die bonding having such a composition, a cured material can be obtained, which has an elastic modulus of 1 MPa to 120 MPa both inclusive at 25° C.

A resin film for die bonding which can be used in this invention can be prepared, for example, by dissolving a resin composition containing the thermoplastic resin and the curable resin as main components and appropriately containing the above additional components in a solvent such as methyl ethyl ketone, acetone, toluene, dimethylformamide, dimethylacetamide and N-methyl-2-pyrrolidone to give a varnish, the applying the varnish onto a mold release sheet using appropriate means such as a comma coater, a die coater and gravure coater, drying the sheet and removing the sheet.

A thickness of the resin film for die bonding is preferably, but not limited to, 3 μm to 100 μm both inclusive, particularly 5 μm to 75 μm both inclusive. When the thickness is within the above range, thickness precision can be particularly conveniently controlled.

In order for an elastic modulus of a cured resin film for die bonding which can be used in the present invention to be 1 MPa to 120 MPa both inclusive at 260° C., it is desirable to combine the thermoplastic resin (particularly, a polyimide resin) exhibiting excellent low elasticity at high temperature and adhesiveness with the thermosetting resin (particularly, an epoxy resin) exhibiting excellent heat resistance and adhesiveness. A combination ratio used can be appropriately adjusted depending on the types of the thermoplastic resin and the thermosetting resin, to reduce a stress due to low elasticity at high temperature without deterioration at high temperature resistance or adhesiveness.

Resin Composition for Encapsulating

A resin composition for encapsulating used in this invention contains an epoxy resin, a phenol resin curing agent, a curing accelerator and an inorganic filler as main components. Furthermore, it is characterized in that a cured material obtained from the resin composition has an elastic modulus of 400 MPa to 1200 MPa both inclusive at 260° C. and has a thermal expansion coefficient of 20 ppm to 50 ppm both inclusive at 260° C., and the product of the elastic modulus at 260° C. of the cured material and thermal expansion coefficient at 260° C. of the cured material is 8000 to 45000 both inclusive.

An elastic modulus of a cured material is determined in accordance with JIS K6911 as a bend elasticconstant. A thermal expansion coefficient of a cured material is measured by TMA (Thermo Mechanical Analysis) at a rising temperature rate of 5° C./min, and specifically can be determined from a thermal expansion coefficient in a TMA curve obtained at 260° C.

An epoxy resin used in a resin composition for encapsulating of this invention is selected from general epoxy-containing monomers, oligomers and polymers; for example, bisphenol type epoxy resins, biphenyl type epoxy resins, stilbene type epoxy resins, hydroquinone type epoxy resins, ortho-cresol novolac type epoxy resins, triphenolmethane type epoxy resins, phenolaralkyl type (containing a phenylene or diphenylene moiety) epoxy resins, naphthalene-containing epoxy resins and dicyclopentadiene type epoxy resins, which can be used alone or in combination. For achieving lower elasticity at high temperature, preferred is a resin having a flexible structure such as a dicyclopentadiene type epoxy resin, but such a low elastic resin at high temperature is high thermal expansion at high temperature, leading to deterioration in crack resistance. It is, therefore, also necessary to reduce thermal expansion coefficient by increasing a filler and to reduce viscosity of the epoxy resin. Thus, for achieving lower elasticity at high temperature and lower thermal expansion coefficient at high temperature, it is preferable to use an epoxy resin exhibiting good balance between flexibility and flowability at high temperature such as biphenyl type epoxy resins, bisphenol type epoxy resins and phenolaralkyl type epoxy resins. A plurality of, but not a single, epoxy resins can be mixed to achieve good balance between flexibility and flowability.

A phenol resin curing agent used in a resin composition for encapsulating in this invention is selected from general monomers, oligomers and polymers having at least two phenolic hydroxy groups capable of form a crosslinked structure by reacting with the above epoxy resin; for example, phenol novolac resins, cresol novolac resins, phenol aralkyl (containing a phenylene or biphenylene moiety) resins, naphthol-aralkyl resins, triphenolmethane resins and dicyclopentadiene type phenol resins, which can be used alone or in combination. As in an epoxy resin, for achieving low elasticity and low thermal expansion coefficient at high temperature, it is preferable to use a phenol resin exhibiting good balance between flexibility and flowability at high temperature such as phenolaralkyl resins and naphtholaralkyl resin. A plurality of, but not a single, phenol resins can be mixed to achieve good balance between flexibility and flowability.

For the epoxy and the phenol resins used in a resin composition for encapsulating in this invention, an equivalent ratio of the number of epoxy groups in the total epoxy resins to the number of phenolic hydroxy groups in the total phenol resins is preferably 0.5 to 2 both inclusive, particularly 0.7 to 1.5 both inclusive. Within the above range, deterioration in moisture resistance or curability can be prevented.

A curing accelerator used in a resin composition for encapsulating in this invention is a compound which can be a catalyst in a crosslinking reaction between the epoxy resin and the phenol resin; for example, but not limited to, amine compounds such as 1,8-diazabicyclo(5,4,0)undecene-7 and tributylamine; organophosphorous compounds such as triphenylphosphine and tetraphenylphosphonium tetraphenylborate; and imidazole compounds such as 2-methylimidazole, which can be used alone or in combination.

There are no particular restrictions to the type of an inorganic filler used in a resin composition for encapsulating in the present invention, and materials commonly used as an encapsulating material can be used; for example, fused silica, crystal silica, secondary condensed silica, alumina, titanium white, aluminum hydroxide, talc, clay and glass fiber, which can be used alone or in combination of two or more. Particularly preferred is fused silica. Both crushed and spherical fused silica can be used, but it is preferable to mainly use spherical silica for increasing a blending rate and minimizing increase in a melt viscosity in an epoxy resin composition. Furthermore, for increasing a blending rate of spherical silica, it is desirable to make a particle size distribution of the spherical silica wider. A blending rate of the total inorganic fillers is preferably 80 wt % to 95 wt % both inclusive in the light of balance between moldability and reliability. A blending rate within the above range can result in preventing deterioration in crack resistance due to increase in a thermal expansion coefficient at high temperature or deterioration in flowability. Increase of the filler tends to increase an elastic modulus at high temperature while reducing a thermal expansion coefficient at high temperature. For achieving lower elasticity and lower thermal expansion coefficient at high temperature by improved crack resistance, it is, therefore, important that the amount of the filler, the epoxy resin and the phenol curing agent are properly combined to realize good balance.

When necessary, an epoxy resin composition used as a resin composition for encapsulating in this invention may appropriately contain, in addition to an epoxy resin, a phenol resin curing agent, a curing accelerator and an inorganic filler, various additives including a flame retardant such as brominated epoxy resins, antimony oxide and phosphorous compounds; an inorganic ion exchanger such as bismuth oxide hydrate; a coupling agent such as γ-glycidoxypropyl-trimethoxysilane; a coloring agent such as carbon black and colcothar, a low-stress component such as silicone oils and silicone rubbers; a mold release such as natural waxes, synthetic waxes, higher fatty acids and their metal salts and paraffins; and an antioxidant. Furthermore, an inorganic filler may be, if necessary, pre-treated with a coupling agent, an epoxy resin or a phenol resin. Such pretreatment can be effected, for example, by dissolving the components in a solvent and then removing the solvent; or directly adding the components to the inorganic filler and then treating the mixture by a blender. Among these additives, addition of a low-stress component such as silicone oils and silicone rubbers tends to reduce an elastic modulus at high temperature and to increase a thermal expansion coefficient at a higher temperature. Thus, a blending ratio can be properly adjusted to improve crack resistance, where a combination of the filler amount, an epoxy resin and a phenol resin curing agent must be well-balanced.

In the resin composition for encapsulating contains epoxy resins and phenol resins such that an equivalent ratio of the number of epoxy groups in the total epoxy resins to the number of phenolic hydroxy groups in the total phenol resins is 0.5 to 2 both inclusive, preferably 0.7 to 1.5 both inclusive, and contains an inorganic filler in an amount of 80 wt % to 95 wt % both inclusive in the resin composition. These ranges can be combined as appropriate.

A resin composition for encapsulating having such a composition can is provide a cured material (a cured encapsulating material) having an elastic modulus of 400 MPa to 1200 MPa both inclusive at 260° C. and a thermal expansion coefficient of 20 ppm to 50 ppm both inclusive at 260° C., and the product of the elastic modulus and thermal expansion coefficient is 8000 to 45000 both inclusive.

The property of the cured encapsulating material is provided by “the product of the elastic modulus at 260° C. and thermal expansion coefficient at 260° C.” in the present investment. It is possible to explain this reason as follows.

The thermal expansion coefficient of the silicon chip and the lead flame at mounting temperature (260° C.) is smaller than that of the cured encapsulating material. Therefore, the delamination between the cured encapsulating material and the silicon chip or the lead frame (hereinafter, optionally referred to as “between members”) may be generated by the stress caused by the heat expansion difference in mounting. The inventors studied zealously the generation of delamination in relation to the characteristic of a cured encapsulating material by using stress analysis procedures such as FEM (finite element method). In the result, the inventors discovered need of reducing the above-mentioned stress to suppress the delamination between materials, that is

i) The thermal expansion coefficient difference between members is reduced,

ii) The elastic modulus of each members is reduced. The inventors studied further zealously. In the result, the inventors discovered that suppressing the generation of delamination becomes difficult so that being not able to reduce the above-mentioned stress when the other side was a large value even if only above-mentioned i) or ii) was small values. In a word, the generation of delamination between members can be suppressed by satisfing both above-mentioned i) and ii).

The relation of the stress generated between members and above-mentioned i) and ii) is able to be simply provided by representing property of cured material as “the product of the elastic modulus at 260° C. and thermal expansion coefficient at 260° C.” in present invention. In addition, the stress is able to be sufficiently reduced because the thermal expansion coefficient difference between the silicon chip or the lead flame and the cured encapsulating material becomes lowers enough and the elastic modulus of each members becomes small enough by making value of the product to a specified range. Therefore, the delamination can be suppressed to effective. In addition, the lower limit is 8,000 or more because the elastic modulus is preferably higher so that the encapsulating materials is desired for the high mechanical characteristic. In addition, for the cured encapsulating material, more than certain value of the mechanical strength that encapsulating/molding is enabled is required. From that point of view, a lower limit value of the elastic modulus that having a high correlation with the mechanical strength is needed 8,000 or more.

For obtaining a cured material having an elastic modulus of 400 MPa to 1200 MPa both inclusive at 260° C. and a thermal expansion coefficient of 20 ppm to 50 ppm both inclusive at 260° C., and the product of the elastic modulus and thermal expansion coefficient is 8000 to 45000 both inclusive, it is more preferable to use an epoxy resin exhibiting good balance between flexibility and flowability at high temperature such as biphenyl type epoxy resins, bisphenol type epoxy resins and phenolaralkyl type epoxy resins and/or a phenol resin exhibiting good balance between flexibility and flowability at high temperature such as phenolaralkyl resins and naphtholaralkyl resins. Furthermore, it is desirable to use spherical silica having wider particle size distribution to increase the content of the total inorganic fillers in the whole epoxy resin composition to as high as about 80 wt % to 95 wt % both inclusive. Alternatively, as long as a linear expansion coefficient at 260° C. is below the upper limit, a low-stress component such as silicone oils and silicone rubbers may be added to reduce an elastic modulus at 260° C.

A resin composition for encapsulating in this invention is prepared by blending an epoxy resin, a phenol resin curing agent, a curing accelerator, an inorganic filler and other additives at room temperature; melt-kneading by kneading means including an extruder such as rollers and a kneader; and, after cooling, pulverizing the mixture.

Method for Manufacturing a Semiconductor Device

There will be described a method for manufacturing a semiconductor device using the resin composition described above, but this invention is not limited to the process below.

First, a semiconductor chip 18 whose surface is coated with a buffer coating film 26 is prepared.

Specifically, a resin composition for buffer coating is applied to a proper base such as a silicon wafer, a ceramic substrate and an aluminum substrate. On the surface of the base, there may be optionally formed a plurality of bonding pads 20 and a passivation film 24 filling the space between the bonding pads 20. The composition can be applied, for example, by spin coating using a spinner, spray coating using a spray coater, immersion, printing or roll coating.

After drying the applied film by pre-baking at 90 to 140° C., a desired pattern is formed by a common exposure process. An actinic ray used for irradiation in the exposure process may be X-ray, electron beam, UV-ray or visible ray, but preferably has a wavelength of 200 to 700 nm.

After the exposure, the applied film is baked. This step can increase a reaction rate of epoxy crosslinking. A temperature condition of the baking is 50 to 200° C., preferably 80 to 150° C., more preferably 90 to 130° C.

Next, unexposed parts are removed by dissolving them in a stripper to obtain a buffer coating film 26 having a relief pattern where a bonding pad 20 has an opening whose bottom is exposed. Examples of such a stripper include hydrocarbons including alkanes and cycloalkanes such as pentane, hexane, heptane and cyclohexane; and aromatics such as toluene, mesitylene and xylene. It may be a terpene such as limonene, dipentene, pinene and mecline; or a ketone such as cyclopentanone, cyclohexanone and 2-heptanone. Preferred is an organic solvent containing these with an appropriate amount of a surfactant.

Development can be conducted by an appropriate method such as spraying, paddling, immersion and sonication. Then, the relief pattern formed after development is rinsed A rinse agent is an alcohol. Next, the pattern is heated at 50 to 200° C. for removing the remaining developing solution and rinse agent, to obtain a highly heat-resistant final pattern in which epoxy groups have been further cured. Then, the patterned silicon wafer can be diced into small pieces, to provide a semiconductor chip 18 whose surface is coated with a buffer coating film 26. A film thickness of the buffer coating film 26 [symbol] film may be about 5 μm.

Then, the semiconductor chip 18 is attached onto a pad 13 in a lead frame 12 via a resin composition for die bonding.

First, there will be described a method for attaching the semiconductor chip 18 using a resin paste as the resin composition for die bonding.

Specifically, the resin paste for die bonding is applied onto the pad 13 in the lead frame 12 by, for example, point application using a multipoint or single-point needle, line application using a single-point needle, screen printing or stamping. Then, the semiconductor chip 18 whose surface is coated with the buffer coating film 26 is mounted on the pad 13. Then, in accordance with a known method, the resin paste is cured by heating in, for example, an oven, a hot plate or an in-line curing apparatus, for attaching the semiconductor chip 18.

On the other hand, the following method is used for attachment of the semiconductor chip 18 using a resin film for die bonding.

Specifically, the semiconductor chip 18 is placed on the pad 13 in the lead flame 12 via a resin film for die bonding. Then, they are pressed at temperature 80 to 200° C. for 0.1 to 30 sec, and then cured by heating in an oven at 180° C. for 60 min.

In this invention, it is preferable that the semiconductor chip 18 whose surface is coated with the buffer coating film 26 is placed on the pad 13 in the lead frame 12 and cured, and then the surface of the buffer coating film 26 is plasma-treated. Plasma treatment is advantageous in that it makes the surface of the buffer coating film 26 coarse and, when using oxygen-containing plasma, resulting in excellent adhesiveness to an epoxy encapsulating resin by being hydrophilic.

Then, a bonding pad 20 in the semiconductor chip 18 is connected with the lead frame 12 via a bonding wire 22 as usual.

Then, electronic parts such as semiconductor chip are encapsulated with the cured encapsulating material 28, to provide a semiconductor device 10. Specifically, using a resin composition for encapsulating, they can be cured/molded by a common molding method such as transfer molding, compression molding and injection molding.

In the semiconductor device 10 obtained by the above manufacturing process,

the buffer coating film 26 has an elastic modulus of 0.5 GPa to 2.0 GPa both inclusive, preferably 0.5 GPa to 1.0 GPa both inclusive at 25° C.,

the cured die bonding material 16 has an elastic modulus of 1 MPa to 120 MPa both inclusive, preferably 5 MPa to 100 MPa both inclusive at 260° C., and

the cured encapsulating material 28 has an elastic modulus of 400 MPa to 1200 MPa both inclusive, preferably 400 MPa to 800 MPa both inclusive at 260° C., and the cured material has a thermal expansion coefficient of 20 ppm to 50 ppm both inclusive, preferably 20 ppm to 40 ppm both inclusive at 260° C., and the product of the elastic modulus of the cured encapsulating material 28 and thermal expansion coefficient of the cured encapsulating material 28 is 8000 to 45000 both inclusive. These ranges may be appropriately combined.

In the semiconductor device of this invention, the buffer coating film 26, the cured die bonding material 16 and the cured encapsulating material 28 have an elastic modulus within the above ranges, so that excellent anti-solder reflow resistance can be achieved in mounting using a lead-free solder, resulting in higher reliability.

It is apparent that the present invention is not limited to the above embodiment, that may be modified and changed without departing from the scope and spirit of the invention.

### EXAMPLES

This invention will be specifically described with reference to, but not limited to, Examples, in which all blending rates are in part(s) by weight.

(1) Preparation of a Resin Composition for Buffer Coating

<<(Preparation of a Resin Composition for Buffer Coating (A-1)>>

A decylnorbornene/glycidyl methyl ether norbornene=70/30 copolymer, Copolymer (A-1) was prepared as follows.

In a thoroughly dried flask were placed ethyl acetate (917 g), cyclohexane (917 g), decylnorbornene (192 g, 0.82 mol) and glycidyl methyl ether norbornene (62 g, 0.35 mol), and the system was degassed for 30 min under a dry nitrogen gas. Into the flask was added a solution of 9.36 g (19.5 mmol) of a nickel catalyst (bistoluene-bisperfluorophenyl-nickel) in 15 mL of toluene, and the mixture was strirred at 20° C. for 5 hours to complete the reaction. Then, a peracetic acid solution (975 mmol) was added. After stirring for 18 hours, the aqueous and the organic solvent layers were separated/extracted. The organic solvent layer was washed with distilled water three times and separated/extracted. Then, methanol was added to the organic solvent layer, to precipitate a cyclic olefin resin insoluble in methanol. The precipitate was collected, washed with water and dried in vacuo to obtain 243 g (yield: 96%) of the cyclic olefin resin. The cyclic olefin resin thus prepared had a molecular weight, Mw=115,366, Mn=47,000, Mw/Mn=2.43 as determined by GPC. The composition of the cyclic olefin resin was decylnorbornene: 70 mol % and epoxy norbornene: 30 mol % as determined by ¹H-NMR

To a solution of 228 g of the cyclic olefin resin thus prepared in 342 g of decahydronaphthalene were added 4-methylphenyl-4-(1-methylethyl)phenyliodonium tetrakis(pentafluorophenyl)borate (0.2757 g, 2.71×10⁻⁴ mol), 1-chloro-4-propoxy-9H-thioxanthone (0.826 g, 2.71×10⁻⁴ mol), phenothiazine (0.054 g, 2.71×10⁻⁴ mol) and 3,5-di-t-butyl-4-hydroxyhydrocinnamate (0.1378 g, 2.60×10⁻⁴ mol), and the resulting solution was filtrated with 0.2 μm fluororesin filter to obtain a resin composition for buffer coating (A-1).

<<A Resin Composition for Buffer Coating (A-2)>>

A resin composition for buffer coating (A-2) was used CRC-6061 (Product name, Sumitomo Bakelite Co., Ltd.)

<<Preparation of a Resin Composition for Buffer Coating (A-3)>>

A resin composition for buffer coating (A-3) was obtained by method as well as the method of preparing (A-1) except the ratio of decylnorbornene/glycidyl methyl ether norbornene=90/10.

<<Evaluation of an Elastic Modulus of a Buffer Coating Film>>

The resin composition for buffer coating obtained as above-mentioned was applied onto a silicon wafer using a spin coater and then dried on a hot plate at 120° C. for 5 min, to obtain an applied film with a thickness of about 10 μm. After curing, a silicon wafer was diced into pieces with a width of 100 mm, and a test piece as a strip was immersed in a 2% aqueous hydrofluoric acid solution to dissolve the silicon wafer substrate. It was washed and dried to obtain a test piece as a film. For the test piece thus obtained, a tensile strength was determined by Tenshiron in accordance with JIS K-6760 to obtain an SS curve, from which a Young's elastic modulus (25° C.). The cured material (the buffer coating film) formed from the above resin composition for buffer coating (A-1) had an elastic modulus of 0.5 GPa. The buffer coating film formed from the above resin composition for buffer coating (A-2) had an elastic modulus of 3.5 GPa. The buffer coating film formed from the above resin composition for buffer coating (A-3) had an elastic modulus of 0.2 GPa. In addition, the evaluation as a package was not carry out because resin composition for buffer coating (A-3) had a problem for exposure.

(2) Preparation of a Resin Paste (A Resin Composition for Die Bonding)

The components shown in Table 1 and a filler were blended and kneaded at room temperature five times using three rolls (roll distance: 50 μm/30 μm), to prepare a resin paste (B-1) and (B-2). The resin paste was defoamed in a vacuum chamber at 2 mmHg for 30 min and then evaluated for an elastic modulas at high temperature as follows. Table 1 shows blending rates and the evaluation results. In this table, a blending rate is in part(s) by weight.

<<Starting Materials>>

The starting materials used were as follows.

Bisphenol-A type epoxy resin (Yuka Shell Epoxy Co., Ltd., EPICOAT 828, epoxy equivalent: 190; hereinafter, referred to as “BPA”),

Cresyl glycidyl ether (Nippon Kayaku Co., Ltd., SBT-H, epoxy equivalent: 206; hereinafter, referred to as “m,p-CGE”),

Dicyandiamide (hereinafter, referred to as “DDA”),

Bisphenol-F type curing agent (Dainippon Ink And Chemicals, Incorporated, DIC-BPF, epoxy equivalent: 156; hereinafter, referred to as “BPF”),

2-Phenyl-4-methyl-5-hydroxymethylimidazole (Shikoku Chemicals Corporation, Curesol 2P4MHZ; hereinafter, referred to as “imidazole”),

Epoxy-containing polybutadiene (Nippon Oil Corporation, E-1800; hereinafter, referred to as “E/1800”), and

Silver powder silver flake powder having an average particle size of 3 μm and a maximum particle size of 30 μm.

<<Evaluation Method for an Elastic Modulus of a Cured Resin Paste (A Cured Die Bonding Material)>>

On a Teflon® sheet was applied a resin paste with a width of 4 mm, a length of about 50 mm and a thickness of 200 μm, and it was cured in an oven at 175° C. for 30 min. Then, the cured material was removed from the Teflon® sheet and processed into a test piece with a length of 20 mm. The test piece was examined by a dynamic viscoelasticity measuring apparatus (trade name: DMS6100 (Seiko Instruments Inc)) at a frequency of 10 Hz while raising a temperature from −100° C. to 330° C. at a rate of 5° C./min, and then a storage elastic modulus at 260° C. was calculated. The results are shown in Table 1.

(3) Preparation of a Resin Film

<<Preparation of a Resin Film Resin Varnish for Die Bonding>>

A resin varnish (B-3) containing a resin solid in 43% was prepared by dissolving 87.0 parts by weight of a polyimide resin PIA (a polyimide resin prepared by reacting 43.85 g (0.15 mol) of 1,3-bis(3-aminophenoxy)benzene (Mitsui Chemicals, Inc., APB) with 125.55 g (0.15 mol) of α,ω-bis(3-aminopropyl)polydimethylsiloxane (average molecular weight: 837)(Fuso Chemical Co. Ltd., G9) as diamine components with 93.07 g (0.30 mol) of 4,4′-oxydiphthalic dianhydride (MANAC Incorporated, ODPA-M) as an acid component); hereinafter, referred to as “PIA”; Tg: 70° C., weight average molecular weight: 30,000) as a thermoplastic resin; 8.7 parts by weight of an epoxy resin (EOCN-1020-80(ortho-cresol novolac type epoxy resin), epoxy equivalent: 200 g/eq., Nippon Kayaku Co., Ltd, softening point: 80° C.; hereinafter, referred to as “EOCN”)as a curable resin; and 4.3 parts by weight of a silane coupling agent (KBM573, Shin-Etsu Chemical Co., Ltd) in N-methyl-2-pyrrolidone (NMP).

A resin varnish (B-4) containing a resin solid in 40% was prepared by dissolving a polyimide resin PIA (a polyimide resin prepared by reacting 43.85 g (0.15 mol) of 1,3-bis(3-aminophenoxy)benzene (Mitsui Chemicals, Inc., APB) with 125.55 g (0.15 mol) of α,ω-bis(3-aminopropyl)polydimethylsiloxane (average molecular weight: 837)(Fuso Chemical Co. Ltd., G9) as diamine components with 93.07 g (0.30 mol) of 4,4′-oxydiphthalic dianhydride (MANAC Incorporated, ODPA-M) as an acid component); hereinafter, referred to as “PIA”; Tg: 70° C., weight average molecular weight: 30,000) in N-methyl-2-pyrrolidone (NMP).

<<Preparation of a Resin Film for Die Bonding>>

The above resin varnish was applied on a polyethylene terephthalate film (Mitsubishi Polyester Film Corporation, Catalog No. MRX50, thickness: 50 μm) as a protective film using a comma coater and was dried at 180° C. for 10 min. Then, the polyethylene terephthalate film as a protective film was peeled to obtain a resin film for die bonding with a thickness of 25 μm.

<<Evaluation Method for an Elastic Modulus of a Cured Resin Film (A Cured Die Bonding Material)>>

The resin film for die bonding was cured in an oven at 180° C. for 60 min. The cured material was examined with a test length of 20 mm by a dynamic viscoelasticity measuring apparatus at a frequency of 10 Hz while raising a temperature from −100° C. to 330° C. at a rate of 5° C./min, and then a storage elastic modulus at 260° C. was calculated. The blending rates and the results are shown in Table 1.

TABLE 1

| | B-1 | B-2 | B-3 | B-4 |
|---|---|---|---|---|
| BPA | 13.0 | 13.0 | | |
| BPF | 6.7 | 4.1 | | |
| PIA | | | 87.0 | 100 |
| m.p-CGE | 8.3 | 7.5 | | |
| DDA | 0.2 | 0.2 | | |
| EOCN | | | 8.7 | |
| Imidazole | 0.2 | 0.2 | | |
| E-1800 | 1.6 | | | |
| Silane coupling agent | | | 4.3 | |
| Silver powder | 70.0 | 75.0 | | |
| Elastic modulus (260° C.)[MPa] | 50 | 150 | 6 | <1 |

(4) Preparation of a Resin Composition for Encapsulating

The components were mixed at room temperature by a mixer, kneaded two rolls at 70 to 120° C., cooled and then pulverized to give an epoxy resin composition for encapsulating. There will be described principal raw materials components used and a property evaluation method for a resin composition obtained.

<<Raw Materials used for an Epoxy Resin Composition for Encapsulating>>

Epoxy resin 1: a phenol aralkyl type epoxy resin having a biphenylene moiety (Nippon Kayaku Co., Ltd., NC3000P, softening point: 58° C., epoxy equivalent: 274),

Epoxy resin 2: an ortho-cresol novolac type epoxy resin (Sumitomo Chemical Co., Ltd., ESCN195LA, softening point: 55° C., epoxy equivalent: 199),

Epoxy resin 3: a phenolphenylaralkyl type epoxy resin (Mitsui Chemicals, Inc., E-XLC-3L, softening point: 53° C., hydroxy equivalent: 236),

Phenol resin 1: a phenolaralkyl resin having a biphenylene moiety (Meiwa Plastic Industries, Ltd. , MEH-7851SS, softening point: 65° C., hydroxy equivalent: 203),

Phenol resin 2: a phenolphenylaralkyl resin (Mitsui Chemicals, Inc., XLC-4L, softening point: 65° C., hydroxy equivalent: 175° C.),

Phenol resin 3: a phenol novolac resin (softening point: 80° C., hydroxy equivalent: 105),

Spherical fused silica: average particle size: 20 μm,

Triphenylphosphine,

Coupling agent: γ-glycidylpropyl-trimethoxysilane,

Carbon black

Carnauba wax, and

Low-stress modifier average particle size: 5 μm, a mixture of NBR powder and talc.

<<Evaluation Method for Physical Properties of a Cured Resin Composition for Encapsulating (A cured Encapsulating Material)>>

TMA (α1, α2, Tg): a transfer molding machine was used to mold a cured material having dimensions of 10 mm×4 mm×4 mm under the conditions of a mold temperature: 175° C., an injection pressure: 6.9 MPa and a curing time: 90 sec. The cured material was post-cured at 175° C. for 2 hours and was subjected to TMA measurement at a rising temperature rate of 5° C./nun. A thermal expansion coefficients at 60° C. and 260° C. on the TMA curve obtained was α1 and α2 respectively, and a glass transfer temperature (Tg) was obtained by reading off a temperature at an intersection of tangent lines at 60° C. and 260° C.

Bend elastic modulus (260° C.): determined in accordance with JIS K6911. A transfer molding machine was used to mold a cured material having dimensions of 80 mm×10 mm×4 nm under the conditions of a mold temperature: 175° C., an injection pressure: 6.9 MPa and a curing time: 90 sec. The cured material was post-cured at 175° C. for 2 hours and was subjected to bend elastic modulus measurement at 260° C. Table 2 show the blending rates and the results. In the table, a blending rate is in part(s) by weight.

TABLE 2

| | C-1 | C-2 | C-3 | C-4 |
|---|---|---|---|---|
| Epoxy resin 1 | 7.3 | 7.5 | | |
| Epoxy resin 2 | | 1.0 | | 12.1 |
| Epoxy resin 3 | | | 6.0 | |
| Phenol resin 1 | 4.2 | 1.1 | 4.0 | |
| Phenol resin 2 | | 3.3 | | |
| Phenol resin 3 | | | | 4.8 |
| Spherical fused silica | 87.5 | 86.0 | 89.0 | 80.0 |
| Triphenylphosphine | 0.2 | 0.3 | 0.2 | 0.3 |
| Coupling agent | 0.3 | 0.3 | 0.3 | 0.3 |
| Carbon black | 0.3 | 0.3 | 0.3 | 0.3 |
| Carnauba wax | 0.2 | 0.2 | 0.2 | 0.2 |
| Low-stress modifier | | | | 2.0 |
| α 1 [ppm/° C.] | 9 | 11 | 8 | 14 |
| α 2 [ppm/° C.] | 38 | 40 | 31 | 55 |
| Tg [° C.] | 130 | 125 | 135 | 150 |
| Elastic modulus E (260° C.)[Mpa | 800 | 1100 | 1500 | 1000 |
| α 2 × F | 30400 | 44000 | 46500 | 55000 |

Package Evaluation Method

### Examples 1 to 4 and Comparative Examples 1 to 7

There will be described a method for assembling a package and an evaluation method. The results are shown in Table 3.

<<Application of a Resin Composition for Buffer Coating to a Semiconductor Chip>>

The prepared resin composition for buffer coating was applied on a slicon wafer formed a circuit by using a spin coater and dried on a hot plate at 120° C. for 5 min. to give an applied film with a thickness of about 10 μm. The applied film was exposed at 300 mJ/cm² through a reticule by an i-ray stepper exposing machine NSR-4425i (Nikon Corporation). Then, the film was heated on a hot plate at 100° C. for 4 min. to accelerate a crosslinking reaction in the exposed area.

It was then immersed in limonene for 30 sec, to dissolve/remove the unexposed part and then rinsed with isopropyl alcohol for 20 sec. Consequently, it was observed that a pattern was formed.

The cyclic olefin resin film was treated by oxygen plasma using a plasma machine (OPM-EM1000, Tokyo Ohka Kogyo Co. Ltd.) under the conditions of output: 400 W, period: 10 min, oxygen flow rate: 200 sccm.

<<Method for Mounting a Semiconductor Chip Using a Resin Paste>>

On a 160-pin LQFP (Low Profile Quad Flat Package) was mounted a buffer-coated semiconductor chip (a size of the semiconductor chip: 7 mm×7 mm, a thickness of the semiconductor chip: 0.35 mm) via a resin paste for die bonding, and it was cured in an oven under the curing conditions: rising from room temperature to 175° C. for 30 min and then maintaining at 175° C. for 30 min. A thickness of the cured resin paste was about 20 μm.

<<Method for Mounting a Semiconductor Chip Using a Resin Film>>

On one side of an adhesive film is attached the rear surface of a wafer with a thickness of 0.35 mm at 150° C., to give a wafer with an adhesive film. Then, a dicing film is attached on the surface of the adhesive film. The semiconductor wafer with the adhesive film was diced (cut) by a dicing saw at a spindle frequency of 30,000 rpm and a dicing speed of 50 mm/sec to give a 7 mm×7 mm semiconductor chip with the dicing film and the adhesive film. The dicing sheet was pressed up from the rear surface to peel the dicing film from the adhesive film. The resulting semiconductor chip with the adhesive film was die-bonded by pressing it to a 160-pin LQFP at 200° C. and 5N for 1.0 sec, and then cured in an oven under the curing conditions: rising from room temperature to 180° C. for 30 min and then maintaining at 180° C. for 60 min

<<Process for Molding a Package Using a Resin Composition for Encapsulating>>

A 160-pin LQFP with a semiconductor chip was encapsulated/molded with a resin paste or resin film using a transfer molding machine under the conditions: mold temperature: 175° C., injection pressure: 6.9 MPa and curing time: 90 sec, and then post-cured at 175° C. for 2 hours to give a sample.

<<Evaluation Method for Anti-Solder Reflow Resistance>>

Each of sixteen samples was treated under the conditions of 85° C. and 60% relative humidity for 168 hours and 85° C. and 85% relative humidity for 168 hours, and then treated by IR reflow (260° C.) for 10 sec. The samples were observed for inner cracks and various interfacial delamination by an ultrasonic test equipment When the location of interfacial delamination was identified by an ultrasonic test equipment, the location thereof was identified by cross-sectional observation. Packages with an inner crack or at least one of various interfacial delamination were rejected as defective. When the number of defective packages was “n”, it was expressed as “n/16”.

TABLE 3

| | | Example | | | | Comparative Example | | | | | | |
|---|---|---|---|---|---|---|---|---|---|---|---|---|
| | | 1 | 2 | 3 | 4 | 1 | 2 | 3 | 4 | 5 | 6 | 7 |
| Buffer coat material | A-1 | ∘ | ∘ | ∘ | ∘ | None | None | | ∘ | ∘ | ∘ | ∘ |
| | A-2 | | | | | | | ∘ | | | | |
| Die bond material | B-1 | ∘ | | ∘ | | ∘ | | ∘ | | | | |
| | B-2 | | | | | | | | | | ∘ | |
| | B-3 | | ∘ | | ∘ | | ∘ | | ∘ | ∘ | | |
| | B-4 | | | | | | | | | | | ∘ |
| Sealer | C-1 | ∘ | ∘ | | | ∘ | ∘ | ∘ | | | ∘ | ∘ |
| | C-2 | | | ∘ | ∘ | | | | | | | |
| | C-3 | | | | | | | | ∘ | | | |
| | C-4 | | | | | | | | | ∘ | | |
| Anti-solder reflow resistance | Die top delamination | 0/16 | 0/16 | 0/16 | 0/16 | 16/16 | 16/16 | 16/16 | 0/16 | 16/16 | 0/16 | 0/16 |
| (85° C./60% RH/168 hrs) | | | | | | (*) | (*) | (*) | | | | |
| | Die-attach layer delamination | 0/16 | 0/16 | 0/16 | 0/16 | 0/16 | 0/16 | 0/16 | 0/16 | 16/16 | 16/16 | 16/16 |
| | Die pad delamination | 0/16 | 0/16 | 0/16 | 0/16 | 0/16 | 0/16 | 0/16 | 16/16 | 16/16 | 0/16 | 16/16 |
| Anti-solder reflow resistance | Die top delamination | 0/16 | 0/16 | 0/16 | 0/16 | 16/16 | 16/16 | 16/16 | 16/16 | 16/16 | 0/16 | 0/16 |
| (85° C./85% RH/168 hrs) | | | | | | (*) | (*) | (*) | | | | |
| | Die-attach layer delamination | 0/16 | 0/16 | 0/16 | 0/16 | 16/16 | 0/16 | 16/16 | 16/16 | 16/16 | 16/16 | 16/16 |
| | Die pad delamination | 0/16 | 0/16 | 8/16 | 2/16 | 16/16 | 6/16 | 16/16 | 16/16 | 16/16 | 16/16 | 16/16 |

(*) was showed that a circuit in semiconductor chip was damaged.

A semiconductor device manufactured according to this invention exhibits excellent anti-solder reflow resistance and higher reliability in mounting using a lead-flee solder because there are used a cured resin composition for buffer coating, a cured resin composition for die bonding and a cured resin composition for encapsulating, which have certain properties such as an elastic modulus.

What is claimed is:

1. A semiconductor device formed by placing a semiconductor chip whose surface is coated with a cured resin composition for buffer coating on a pad in a lead frame via a cured resin composition for die bonding and encapsulating the semiconductor chip on the pad in the lead frame by a cured resin composition for encapsulating, wherein
the cured resin composition for buffer coating has an elastic modulus of 0.5 GPa to 2.0 GPa both inclusive at 25° C.;
the cured resin composition for die bonding has an elastic modulus of 1 MPa to 120 MPa both inclusive at 260° C.; and
the cured resin composition for encapsulating has an elastic modulus of 400 MPa to 1200 MPa both inclusive at 260° C. and a thermal expansion coefficient of 20 ppm to 50 ppm both inclusive at 260° C., and the product of the elastic modulus of the cured resin composition for encapsulating and thermal expansion coefficient of the cured resin composition for encapsulating is 8000 to 45000 both inclusive.

2. The semiconductor device as claimed in claim 1, wherein the resin composition for buffer coating comprises an addition (co)polymer containing a structural unit derived from a norbornene type monomer represented by general formula (1): 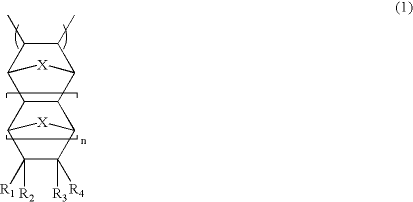
(wherein Xs independently represent O, CH₂ or (CH₂)₂, a plurality of Xs may be, if present, the same or different; n is an integer of 0 to 5; and R1 to R4 independently represent hydrogen, an alkyl-, alkenyl-, alkynyl-, allyl-, aryl-, aralkyl- or ester-containing organic group, an ketone-containing organic group, an ether-containing organic group or an epoxy-containing organic group and R1 to R4 may be the same or different in a plurality of structural units, provided that at least one of R1 to R4 in the total structural units is an epoxy-containing organic group).

3. The semiconductor device as claimed in claim 1, wherein the resin composition for die bonding comprises one or more thermosetting resins selected from the group consisting of hydrogenated bisphenol-A type epoxy resins, 1,4-cyclohexanedimethanol diglycidyl ether, 1,4-butanediol diglycidyl ether, 1,6-hexanediol diglycidyl ether, dicyclopentadiene type epoxy resins and compounds having a radical-polymerizable functional group within a molecule.

4. The semiconductor device as claimed in claim 1, wherein the resin composition for die bonding comprises a polyimide resin prepared by a polycondensation reaction of tetracarboxylic dianhydride and a diaminopolysiloxane represented by general formula (2): 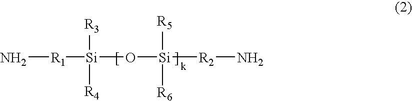
(wherein R1 and R2 independently represent an aliphatic hydrocarbon group having 1 to 4 carbon atoms or aromatic hydrocarbon; and R3, R4, R5 and R6 independently represent an aliphatic hydrocarbon group or aromatic hydrocarbon having 1 to 4 carbon atoms) and an aromatic or aliphatic diamine, and
one or more epoxy resins selected from the group consisting of cresol novolac type epoxy compounds, phenol novolac type epoxy compounds, bisphenol-A type diglycidyl ethers, bisphenol-F type diglycidyl ethers, bisphenol-A epichlorohydrin type epoxy compounds, diphenyl ether type epoxy compounds, biphenyl type epoxy compounds and hydrogenated bisphenol-A type epoxy compounds.

5. The semiconductor device as claimed in claim 1, wherein the resin composition for encapsulating comprises,
one or more resins selected from the group consisting of biphenyl type epoxy resins, bisphenol type epoxy resins, phenolaralkyl type epoxy resins, phenolaralkyl resins and naphtholaralkyl resins, and
an inorganic filler in 80 wt % to 95 wt % both inclusive in the resin composition.

6. A resin composition for buffer coating used for a semiconductor device formed by placing a semiconductor chip whose surface is coated with a cured resin composition for buffer coating on a pad in a lead frame via a cured resin composition for die bonding and encapsulating the semiconductor chip on the pad in the lead frame by a cured resin composition for encapsulating, wherein
the cured resin composition for buffer coating has an elastic modulus of 0.5 GPa to 2.0 GPa both inclusive at 25° C.

7. A resin composition for die bonding used for a semiconductor device formed by placing a semiconductor chip whose surface is coated with a cured resin composition for buffer coating on a pad in a lead frame via a cured resin composition for die bonding and encapsulating the semiconductor chip on the pad in the lead flame by a cured resin composition for encapsulating, wherein
the cured resin composition for die bonding has an elastic modulus of 1 MPa to 120 MPa both inclusive at 260° C.

8. A resin composition for encapsulating used for a semiconductor device formed by placing a semiconductor chip whose surface is coated with a cured resin composition for buffer coating on a pad in a lead frame via a cured resin composition for die bonding and encapsulating the semiconductor chip on the pad in the lead flame by a cured resin composition for encapsulating, wherein
the cured resin composition for encapsulating has an elastic modulus of 400 MPa to 1200 MPa both inclusive at 260° C. and a thermal expansion coefficient of 20 ppm to 50 ppm both inclusive at 260° C., and the product of the cured resin composition for encapsulating and thermal expansion coefficient of the cured resin composition for encapsulating is 8000 to 45000 both inclusive.
